(19) United States
(12) Patent Application Publication
(10) Pub. No.: US 2008/0001619 A1
(43) Pub. Date: Jan. 3, 2008

(54) Display panel lighting test apparatus, and test line employing the same

(75) Inventor: Jin Igarashi, Miyazaki (JP)

Correspondence Address: STAAS & HALSEY LLP, SUITE 700, 1201 NEW YORK AVENUE, N.W., WASHINGTON, DC, 20005, US

(73) Assignee: Fujitsu Hitachi Plasma Display Limited, Miyazaki (JP)

(21) Appl. No.: 11/713,021

(22) Filed: Mar. 2, 2007

(30) Foreign Application Priority Data
Jun. 29, 2006 (JP) 2006-180009

(51) Int. Cl. G01R 31/00

(52) U.S. Cl. 324/770

(57) ABSTRACT

A display panel lighting test apparatus includes: a panel holder which holds a display panel in a removable manner; and a holder base on which the panel holder is removably mounted for supplying electric power and an image signal to the panel holder. The panel holder includes a mount base on which the display panel is removably mounted, a drive circuit which receives the electric power and the image signal from the holder base and outputs a display panel lighting signal, and a press-fit connection member which is removably attached to the display panel to establish press-fit connection between an electrode terminal of the display panel and a signal terminal of the drive circuit by a resilient force of a resilient member thereof.

### CROSS-REFERENCE TO RELATED APPLICATION

This application is related to Japanese patent application No. 2006-180009 filed on Jun. 29, 2006 whose priority is claimed under 35 USC §119, the disclosure of which is incorporated by reference in its entirety.

### BACKGROUND OF THE INVENTION

1. Field of the Invention

The present invention relates to a display panel lighting test apparatus and a test line employing the apparatus. Particularly, the invention relates to a lighting test apparatus which performs a lighting test by inputting a lighting signal to a display panel to cause the display panel to emit light for display before a drive circuit is mounted on the display panel in a production process for a flat panel display such as a liquid crystal display or a plasma display, and to a test line employing the apparatus.

2. Description of the Related Art

Flat panel displays are generally produced by mounting a drive circuit and the like on a display panel. In the production process, a lighting test is performed by inputting a lighting signal to the panel before the mounting of the drive circuit for screening out a defective panel.

A conventionally known method for the lighting test on the display panel is to use lighting test probe pins. Another known method is such that electrodes provided on a flexible printed circuit (FPC) for connection between a circuit board and the panel are used instead of the probe pins as a lighting test probe (see, for example, Japanese Unexamined Patent Publication No. 2004-170242).

However, where display panels to be tested are changed from one lot to another, it is necessary to change signal inputting means according to the geometry of electrode terminals of the display panels in the conventional method, because the number and pitch of the electrode terminals vary depending on the lot of display panels. In this case, it is also necessary to change lighting signal supplying means. Where the lot of display panels to be tested is frequently changed, the capacity utilization of a lighting test apparatus is reduced, resulting in reduced productivity.

### SUMMARY OF THE INVENTION

In view of the foregoing, the present invention provides a display panel lighting test apparatus which reduces operation time required for the changeover of the lot of display panels and improves the operating efficiency of the display panel lighting test.

According to the present invention, there is provided a display panel lighting test apparatus for performing a lighting test on a display panel, which includes: a panel holder which holds the display panel in a removable manner; and a holder base on which the panel holder is removably mounted for supplying electric power and an image signal to the panel holder; the panel holder comprising a mount base on which the display panel is removably mounted, a drive circuit which receives the electric power and the image signal from the holder base and outputs a display panel lighting signal, and a press-fit connection member which is removably attached to the display panel to establish press-fit connection between an electrode terminal of the display panel and a signal terminal of the drive circuit by a resilient force of a resilient member thereof.

The inventive lighting test apparatus makes it easy to connect the electric power and the image signal to the display panel for the lighting test with the use of the panel holder conforming to the type (specifications) of the display panel to be tested. In addition, the connection is achieved and maintained without the use of power such as air pressure or electric power. Therefore, variations between the different types of display panels are completely accommodated by the panel holders, thereby improving the operating efficiency of the display panel lighting test.

### BRIEF DESCRIPTION OF THE DRAWINGS

FIG. 1 is an exploded perspective view of a PDP according to the present invention.

FIG. 2 is a diagram for explaining a PDP production line according to the present invention.

FIG. 3 is an enlarged view of a major portion of an electrode terminal portion of the PDP according to the present invention.

FIGS. 4(a) and 4(b) are diagrams for explaining a lighting test apparatus according to the present invention.

FIG. 5 is an enlarged diagram for explaining a major portion of the lighting test apparatus according to the present invention.

FIG. 6 is a diagram for explaining a lighting test line according to the present invention.

FIG. 7 is a diagram for explaining a variation of the lighting test line according to the present invention.

### DETAILED DESCRIPTION OF THE INVENTION

A display panel lighting test apparatus of the present invention includes: a panel holder which holds the display panel in a removable manner; and a holder base on which the panel holder is removably mounted for supplying electric power and an image signal to the panel holder, wherein the panel holder comprises: a mount base on which the display panel is removably mounted; a drive circuit which receives the electric power and the image signal from the holder base and outputs a display panel lighting signal; and a press-fit connection member which is removably attached to the display panel to establish press-fit connection between an electrode terminal of the display panel and a signal terminal of the drive circuit by a resilient force of a resilient member thereof.

The press-fit connection member may include a contact member which brings the electrode terminal of the display panel and the signal terminal of the drive circuit into contact with each other, and the resilient member is a biasing member which applies a pressure to the contact member.

The panel holder may include plural types of panel holders for different types of display panels, and one of the plural types of panel holders which conforms to the display panel to be tested is mounted on the holder base.

The panel holder may have a handle for transportation.

The resilient member may be a compression spring.

A test line of the present invention includes: a panel stocker which stocks a plurality of display panels to be tested; a holder stocker which stocks a plurality of panel holders; a panel mounting section which receives one of the display panels, selects one of the panel holders conforming to the received display panel, and mounts the received display panel on the selected panel holder; a holder base on which the display panel mounted on the panel holder is tested for lighting; a detaching section which detaches the tested display panel from the panel holder; and a recovering section which recovers the panel holder from the detaching section to the holder stocker.

The panel holders may be each adapted to hold the display panel to be tested in a removable manner, the holder base being adapted to hold the selected panel holder in a removable manner, and supply electric power and an image signal to the selected panel holder, the panel holder including: a mount base on which the display panel to be tested is removably mounted; a drive circuit which receives the electric power and the image signal from the holder base and outputs a display panel lighting signal; and a press-fit connection member which is removably attached to the mounted display panel to establish press-fit connection between an electrode terminal of the mounted display panel and a signal terminal of the drive circuit by a resilient force of a resilient member thereof.

The press-fit connection member of the test line may include a contact member which brings the electrode terminal of the mounted display panel and the signal terminal of the drive circuit into contact with each other, and the resilient member is a biasing member which applies a pressure to the contact member.

The plurality of panel holders of the test line may include plural types of panel holders for different types of display panels, and one of the plural types of panel holders which conforms to the display panel to be tested is mounted on the holder base.

The panel holders of the test line may each have a handle for transportation.

The resilient member of the test line may be a compression spring.

With reference to the attached drawings, the present invention will hereinafter be described in detail by way of embodiments thereof. However, it should be understood that the invention be not limited to the embodiments.

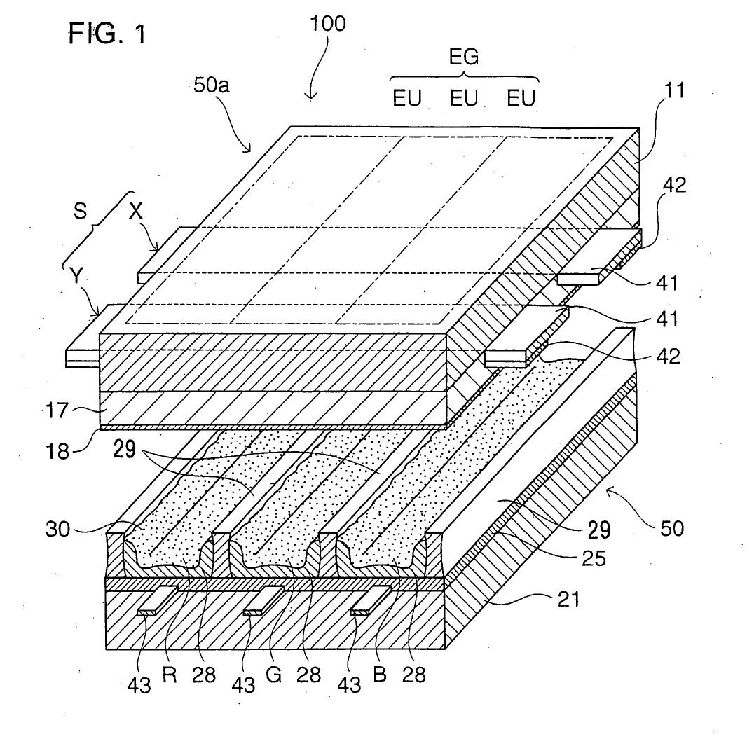

A plasma display panel (hereinafter referred to as “PDP”) to be produced by a production line according to the present invention includes a plurality of discharge cells disposed in a matrix between two opposed substrates. More specifically, a PDP100 includes a rear substrate assembly 50 and a front substrate assembly 50a in pair as shown FIG. 1. In FIG. 1, a single pixel is shown, which includes three RGB cells.

The front substrate assembly 50a includes electrodes X, Y disposed on an inner surface of a glass substrate 11 as extending laterally for causing surface discharge along the substrate surface. These electrodes X, Y are paired to serve as display electrode pairs S for defining display lines. The electrodes X, Y each include an elongated transparent electrode 41 of an ITO thin film having a greater width, and an elongated bus electrode 42 of a metal thin film having a smaller width.

The bus electrode 42 is an auxiliary electrode for ensuring proper electrical conductivity. The electrodes X, Y are covered with a dielectric layer 17, which is in turn covered with a protection film 18. The dielectric layer 17 and the protection film 18 are pervious to light.

The rear substrate assembly 50 includes address electrodes 43 disposed on an inner surface of a glass substrate 21 as extending perpendicularly to the display electrode pairs S, a dielectric layer 25 covering the address electrodes 43, and linear ribs (partition walls) 29 respectively provided between adjacent pairs of address electrodes 43 on the dielectric layer 25. The ribs 29 may be arranged in a grid pattern.

In the rear substrate assembly 50, the ribs 29 partition a discharge space 30 into discharge cells to define sub-pixels (unit light emitting areas) EU, and define the height of the discharge space 30 (or a gap dimension).

Fluorescent layers 28 of three colors R, G, B for full color display respectively cover wall surfaces of the rear substrate assembly 50 each including an upper surface portion of the dielectric layer 25 and side surfaces of the rib 29.

The ribs 29 are each formed of a rib material consisting essentially of a lower melting point glass material, and may be transparent or opaque depending on the type of an additive added to the rib material. The formation of the ribs 29 is achieved by forming a flat lower-melting-point glass layer, forming a cutting mask on the flat glass layer, and patterning the glass layer by a sand blast method.

In matrix display, each line corresponds to a single display electrode pair S, and each row corresponds to a single address electrode 43. Each pixel (picture element) EG is defined by three rows. That is, the pixel EG includes three sub-pixels EU of R, G, B arranged in a line direction.

Wall charges are generated on the dielectric layer 17 for selecting a cell for display by causing opposed discharge (address discharge) between the corresponding address electrode 43 and the corresponding electrode Y. When pulses are alternately applied to the corresponding electrodes X, Y, surface discharge (main discharge) for display occurs in a sub-pixel EU in which the wall charges are generated by the address discharge.

The fluorescent layers 28 are each locally excited by ultraviolet radiation generated by the surface discharge to emit visible light of a predetermined color. The visible light thus emitted passes through the glass substrate 11 to be outputted as display light. Since the ribs 29 are arranged in a so-called stripe pattern, cells in each row in the discharge space 30 are continuous across all the lines in a row direction. Sub-pixels EU in each row emit the same color light.

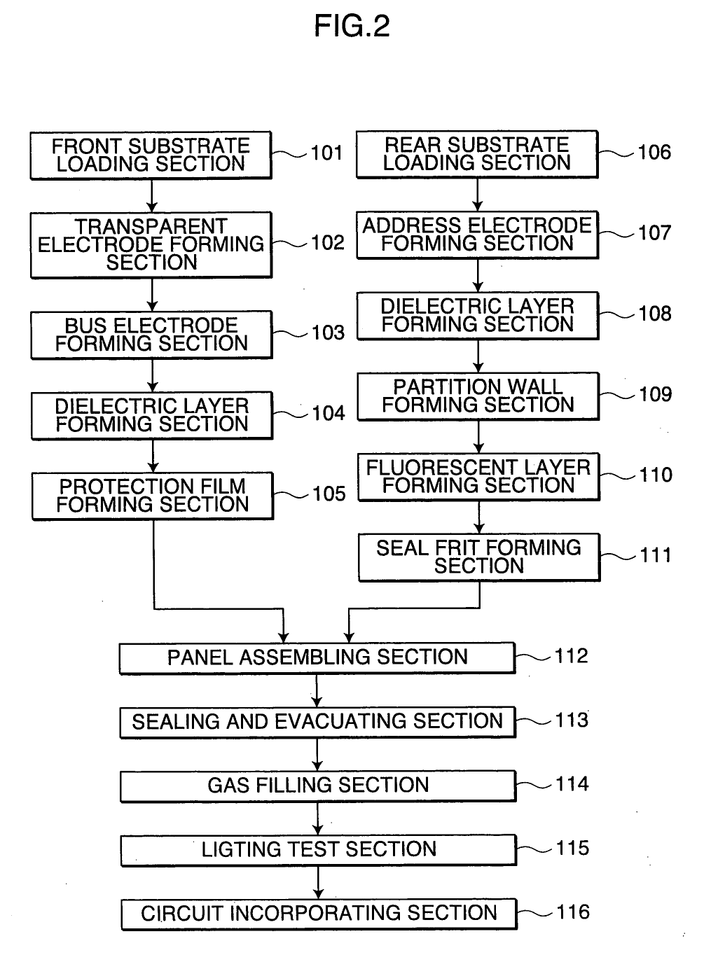

Next, a production line for the PDP will be described with reference to FIG. 2.

First, a glass substrate 11 is transported into a front substrate loading section 101, and elongated transparent electrodes 41 of ITO are formed on a surface of the substrate 11 in a transparent electrode forming section 102 by forming and patterning an ITO film by employing an evaporation method or a sputtering method and an etching method in combination.

Then, bus electrodes 42 of a metal are respectively formed on one-side edges of the transparent electrodes 41 in a bus electrode forming section 103 by employing a printing method or the like.

Subsequently, a dielectric layer 17 and a protection film 18 are formed over the resulting substrate 11 in a dielectric layer forming section 104 and a protection film forming section 105, respectively, whereby a front substrate assembly 50a is provided.

On the other hand, a glass substrate 21 is transported into a rear substrate loading section 106, and address electrodes 43 of a metal are formed on the substrate 21 in an address electrode forming section 107 by employing a printing method or the like. Then, a dielectric layer 25 is formed over the address electrodes 43 in a dielectric layer forming section 108. Further, partition walls 29 are formed on the resulting substrate 21 in a partition wall forming section 109, and fluorescent layers 28 are formed on the resulting substrate 21 in a fluorescent layer forming section 110.

Subsequently, a seal frit material is applied onto a peripheral edge portion of a surface of the substrate 21 in a seal frit forming section 111 by a printing method or the like. Thus, a seal frit is formed on the peripheral edge portion of the substrate 21, whereby a rear substrate assembly 50 is provided.

In turn, the front substrate assembly 50a and the rear substrate assembly 50 are combined together as shown in FIG. 1 in a panel assembling section 112. Then, the seal frit disposed between the assemblies 50 and 50a is heated, and an evacuating operation is performed in a sealing and evacuating section 113. Thus, the front and rear substrate assemblies 50a, 50 are bonded to each other (and sealed), and an inside space defined between the bonded assemblies 50 and 50a is evacuated.

Then, a discharge gas is filled in the inside space (cells) in a gas filling section 114, whereby a PDP 100 is provided.

Subsequently, a lighting test is performed on the PDP 100 in a test line of a lighting test section 115 by employing a lighting test apparatus to be described later. If the tested PDP 100 is acceptable, a drive circuit is mounted on the PDP 100 in a circuit incorporating section 116. Thus, a PDP module is provided.

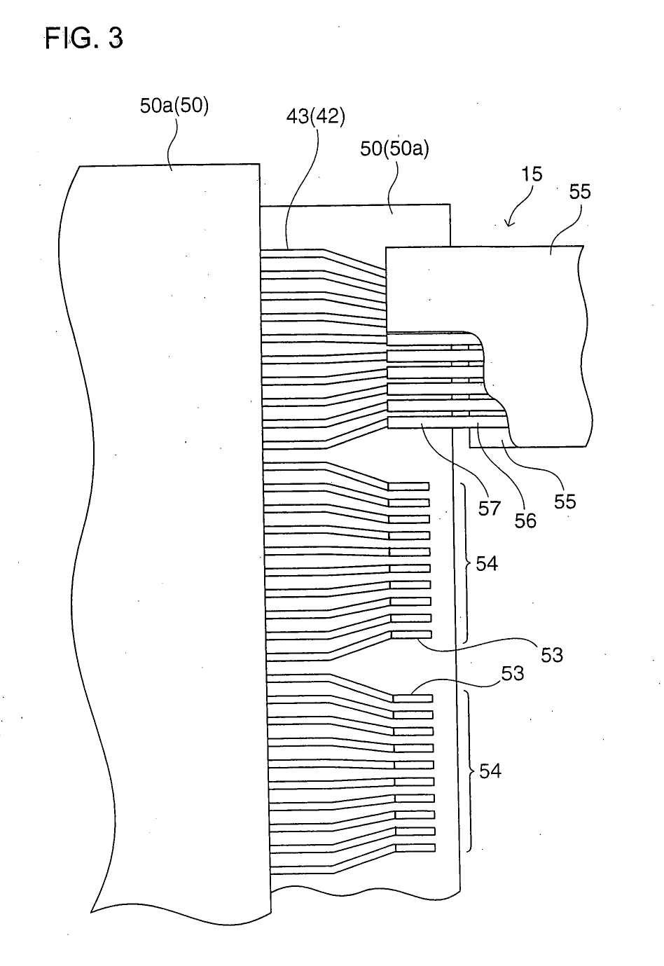

FIG. 3 is a schematic diagram illustrating an edge portion of the PDP 100 when a lighting signal is supplied to the PDP 100 by the lighting test apparatus in the test line of the lighting test section 115. As shown in FIG. 1, with the front substrate assembly 50a and the rear substrate assembly 50 combined in opposed relation, the bus electrodes 42 and the address electrodes 43 are arranged perpendicularly to each other, and extend to edge portions of the respective substrates of the PDP 100.

As shown in FIG. 3, a plurality of electrode terminal blocks 54 are provided in peripheral edge portions of the assemblies 50a, 50. The electrode terminal blocks 54 each have a plurality of electrode terminals 53 respectively extending from the bus electrodes 42 or the address electrodes 43. In the lighting test, the electrode terminal blocks 54 are each kept in contact with a signal terminal portion 15 for supplying lighting signals (panel driving signals) as will be described later.

The signal terminal portion 15 is a flexible printed circuit (FPC) which includes upper and lower insulation films 55 and an electrically conductive pattern 56 of a copper foil provided between the two insulation films 55. More specifically, the signal terminal portion 15 includes signal terminals 57 formed by exposing distal end portions of the electrically conductive pattern 56 from one of the insulation films 55 for electrical connection to the electrode terminals 53 of the PDP 100.

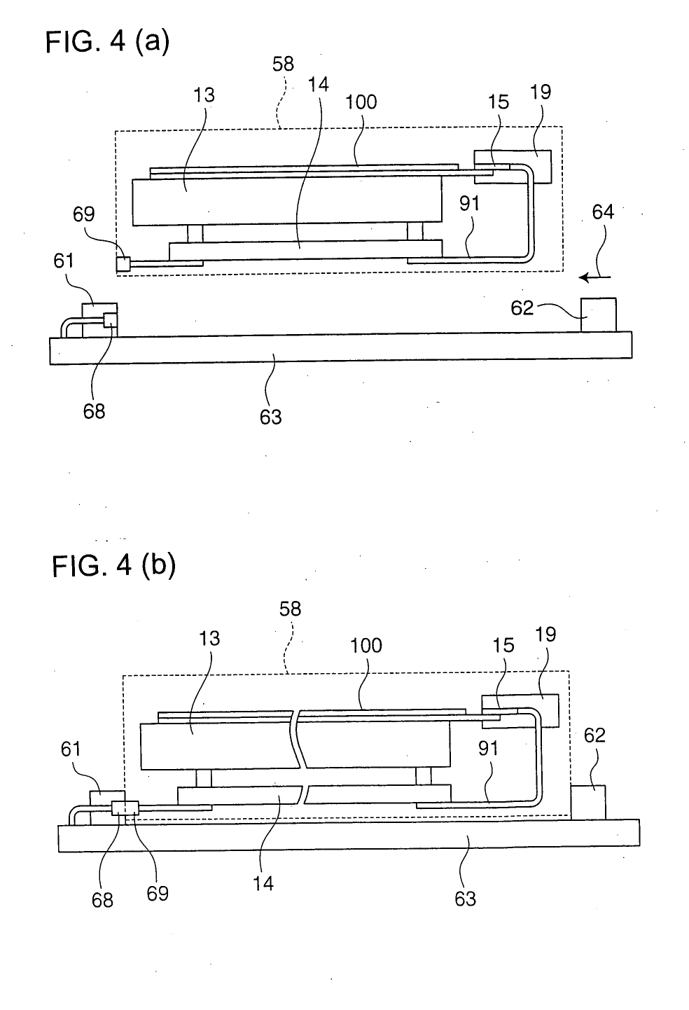

FIGS. 4(a) and 4(b) are schematic diagrams for explaining a panel holder 58 of the lighting test apparatus. Particularly, FIG. 4(a) is a diagram illustrating a state in which the panel holder 58 is detached from a holder base 63, and FIG. 4(b) is a diagram illustrating a state in which the panel holder 58 is attached to the holder base 63.

The panel holder 58 includes a panel mount base 13 for holding the PDP 100 to be tested. A drive circuit 14 is attached to a rear side of the panel mount base 13 for generating signals to turn on the PDP 100 for lighting in the lighting test. The signals generated by the drive circuit 14 are supplied to the PDP 100 via an FPC 91 and the signal terminal portions 15.

The drive circuit 14 may be a drive circuit to be actually used for display or a circuit dedicated for the test.

The signal terminal portions 15 are connected to the PDP 100 by press-fit connection members 19 which press the electrode terminals 53 of the PDP 100 and the signal terminals 57 of the signal terminal portions 15 into contact with each other.

The press-fit connection members 19 are located in positions associated with the electrode terminal blocks 54 (FIG. 3) of the PDP 100.

The panel holder 58 is removably mounted on the holder base 63, and fixed to the holder base 63 by holder fixing portions 61, 62. More specifically, after the panel holder 58 is mounted on the holder base 63, the holder fixing portion 62 is moved in an arrow direction 64 to fix the panel holder 58.

The panel holder 58 further includes a handle for transportation, so that a test operator can transport the panel holder 58.

In FIGS. 4(a) and 4(b), reference numerals 68, 69 denote connectors for electrical connection between the drive circuit 14 and the holder base 63. Therefore, electric power and image signals are supplied from the holder base 63 to the drive circuit 14 for the lighting test via the connectors 68, 69.

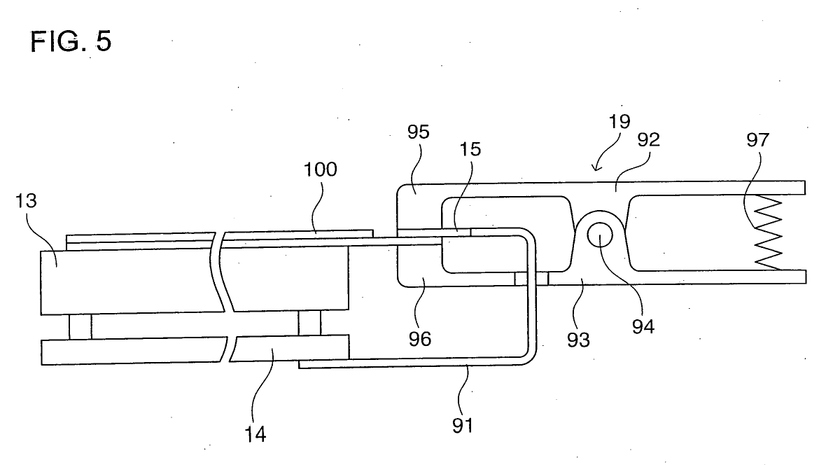

FIG. 5 is a diagram for explaining the press-fit connection members 19 in detail.

The press-fit connection members 19 each include an upper arm 92 and a lower arm 93, which are supported pivotally about a pivot shaft 94.

The upper arm 92 and the lower arm 93 respectively have an upper jaw 95 and a lower jaw 96 at one-side ends thereof, and a compression spring 97 is attached to the other-side ends thereof. The upper jaw 95 and the lower jaw 96 are biased toward each other by the compression spring 97 for pressing the signal terminals 57 (FIG. 3) of the signal terminal portion 15 of the lighting test apparatus to the electrode terminals 53 of the PDP 100.

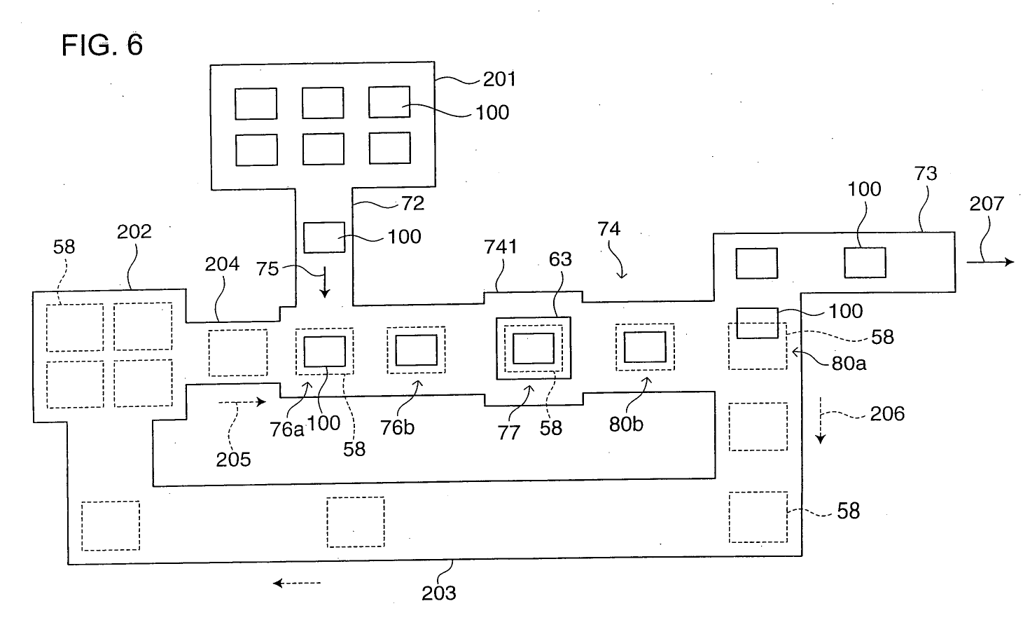

FIG. 6 is a diagram for explaining the overall construction of the test line of the lighting test section 115 (FIG. 2). In FIG. 6, a reference numeral 72 denotes a panel feed conveyor on which a PDP 100 to be subjected to the lighting test is fed out of a panel stocker 201, and a reference numeral 73 denotes a panel unloading conveyor on which a PDP 100 subjected to the lighting test is transported in an arrow direction 207. A lighting test line 74 for performing the lighting test on the PDP 100 is disposed between the panel feed conveyor 72 and the panel unloading conveyor 73.

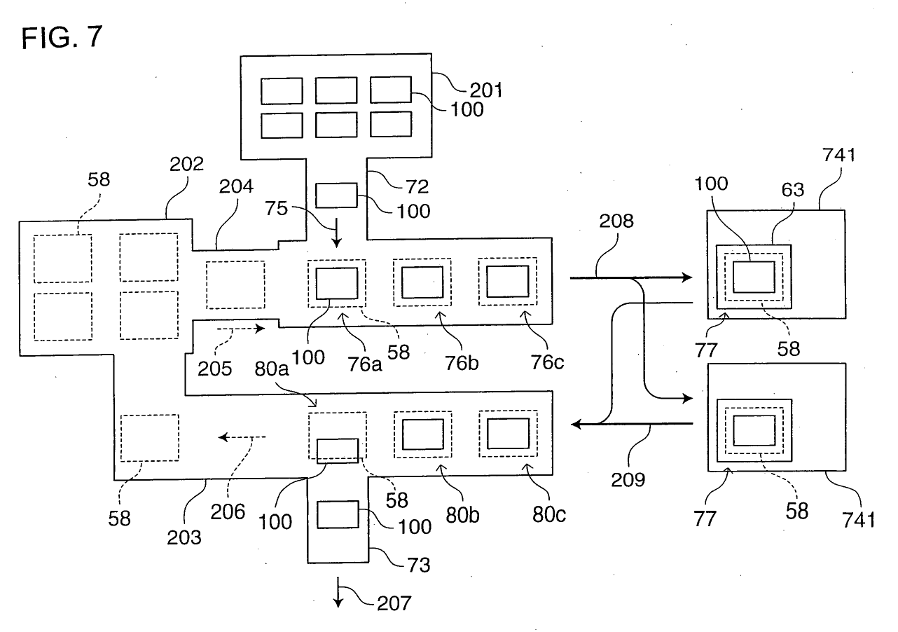

A lighting test area 741 is provided in the test line 74. The lighting test area 741 may be located outside the line as shown in FIG. 7. In this case, the lighting test can be efficiently performed by providing a plurality of lighting test areas 741 (two lighting test areas 741 in FIG. 7) outside the line.

The PDP lighting test to be performed in the line will hereinafter be described.

First, one of PDPs 100 contained in the panel stocker 201 is transported in an arrow direction 75 on the panel feed conveyor 72.

A panel holder 58 conforming to the type (specifications) of the transported PDP 100 is selected from a plurality of panel holders 58 contained in a holder stocker 202, and transported in an arrow direction 205 on a holder feed conveyor 204. The PDP 100 is mounted on the panel holder 58 in a panel mounting position 76a. That is, the PDP 100 is fixed to the panel mount base 13 of the panel holder 58 as shown in FIG. 4(a). Thereafter, the signal terminal portions 15 of the lighting test apparatus are connected to the electrode terminals 53 of the PDP 100 by the press-fit connection members 19 in a press-fit connection member connecting position 76b.

In the test line shown in FIG. 6, the panel holder 58 on which the PDP 100 is mounted with its electrode terminals 53 connected to the signal terminal portions 15 is transported to a lighting test position 77 in the lighting test area 741, and mounted on the holder base 63 in the lighting test position 77 as shown in FIG. 4(b) by a lighting test operator. In the test line shown in FIG. 7, on the other hand, the panel holder 58 on which the PDP 100 is mounted is transported to an unloading port 76c by an unloading conveyor, and transported in an arrow direction 208 to one of the lighting test areas 741 (manually or with the use of a carriage) and mounted on the holder base 63 by the lighting test operator. Then, the holder fixing portion 62 is moved in the arrow direction (holder fixing direction) 64 as shown in FIG. 4(a), whereby the panel holder 58 is fixed onto the holder base 63. At this time, the connectors 68, 69 are connected to each other.

It is noted that the panel holder 58 may be mechanically mounted and fixed onto the holder base 63.

In this state, the lighting test is performed on the PDP 100. The electric power and the image signals are supplied to the connector 69 of the panel holder 58 from the holder base 63 via the connector 68. The electric power and the image signals received by the connector 69 are further supplied to the lighting test drive circuit 14, which generates signals (lighting signals) to turn on the PDP 100 for lighting. The lighting signals are supplied to the PDP 100 via the signal terminal portions 15, whereby the PDP 100 is lit. The lighting state of the PDP 100 is visually inspected, or inspected through automatic recognition.

In the test line shown in FIG. 6, after completion of the PDP lighting test, the panel holder 58 is detached from the holder base 63 in the lighting test position 77, and the press-fit connection members 19 of the panel holder 58 are detached from the PDP 100 in a press-fit connection member detaching position 80b. Then, the panel holder 58 is moved to a panel detaching position 80a. In the panel detaching position 80a, the PDP 100 is detached from the panel holder 58, and transported in an arrow direction (panel unloading direction) 207 on the panel unloading conveyor 73. The panel holder 58 is transported in an arrow direction 206 on a holder recovering conveyor 203, and recovered in the holder stocker 202.

In the test line shown in FIG. 7, the panel holder 58 is detached from the holder base 63 in the lighting test position 77, then transported in an arrow direction 209 to a loading port 80c of the line by the lighting test operator, and loaded into the line by a loading conveyor. Then, the press-fit connection members 19 of the panel holder 58 are detached from the PDP 100 in a press-fit connection member detaching position 80b, and transported to a panel detaching position 80a. The panel detaching step and the subsequent steps are performed in the same manner as in the test line shown in FIG. 6.

Where the lot of PDPs 100 to be tested is changed, the pitch and number of the signal terminals 57 of the signal terminal portions 15, of the lighting test apparatus should be changed according to the pitch and number of the electrode terminals 53 of the electrode terminal blocks 54 (FIG. 3) which may vary depending on the lot of PDPs 100. In response to the changeover of the lot of PDPs 100, the signal terminal portions 15 should be changed according to the geometry of the electrode terminal blocks 54 of a PDP 100 to be next tested.

In the display panel lighting test apparatus according to this embodiment, plural types of panel holders 58 are prepared for different types of PDPs 100 which are different in the pitch and number of the terminals of the electrode terminal blocks 54 thereof and the size thereof.

Therefore, the lighting test can be properly performed simply by selecting a panel holder 58 suitable for the PDPs 100 in response to the changeover of the lot of PDPs. In the case of small lot production of various types of PDPs, which requires frequent lot changeover, time required for the lot changeover is significantly reduced, thereby improving the capacity utilization of the lighting test apparatus. Thus, the operating efficiency of the PDP lighting test is improved.

In the embodiment described above, the signal terminals 57 formed by exposing the distal portions of the electrically conductive pattern 56 of the FPC as shown in FIG. 3 are brought into press contact with the electrode terminals 53 of the PDP 100 for connection. However, the connection method is not limited to this method. For example, the following arrangements are conceivable for the connection.

### (1) A bump (protuberance) is formed on at least one of the electrode terminal 53 and the signal terminal 57 to improve electrical contact.

### (2) A connector which includes connector pins each having a spring property is connected to a distal end of the FPC 91, and the connector pins are used as the signal terminals 57.

(3) Connector pins each having no spring property are provided on the distal end of the FPC 91, and brought into press-fit connection to the electrode terminals 53 by a press-fit connection member 19 having a rubber member capable of evenly pressing the connector pins.

The press-fit connection member 19 is not limited to the aforementioned one, but may be arranged to have a spring property in itself.

What is claimed is:

1. A display panel lighting test apparatus for performing a lighting test on a display panel, the apparatus comprising:
a panel holder which holds the display panel in a removable manner; and
a holder base on which the panel holder is removably mounted for supplying electric power and an image signal to the panel holder,
wherein the panel holder comprises:
a mount base on which the display panel is removably mounted;
a drive circuit which receives the electric power and the image signal from the holder base and outputs a display panel lighting signal; and
a press-fit connection member which is removably attached to the display panel to establish press-fit connection between an electrode terminal of the display panel and a signal terminal of the drive circuit by a resilient force of a resilient member thereof.

2. A display panel lighting test apparatus as set forth in claim 1, wherein the press-fit connection member includes a contact member which brings the electrode terminal of the display panel and the signal terminal of the drive circuit into contact with each other, and the resilient member is a biasing member which applies a pressure to the contact member.

3. A display panel lighting test apparatus as set forth in claim 1, wherein the panel holder includes plural types of panel holders for different types of display panels, and one of the plural types of panel holders which conforms to the display panel to be tested is mounted on the holder base.

4. A display panel lighting test apparatus as set forth in claim 1, wherein the panel holder has a handle for transportation.

5. A display panel lighting test apparatus as set forth in claim 1, wherein the resilient member is a compression spring.

6. A test line comprising:
a panel stocker which stocks a plurality of display panels to be tested;
a holder stocker which stocks a plurality of panel holders;
a panel mounting section which receives one of the display panels, selects one of the panel holders conforming to the received display panel, and mounts the received display panel on the selected panel holder;
a holder base on which the display panel mounted on the panel holder is tested for lighting;
a detaching section which detaches the tested display panel from the panel holder; and
a recovering section which recovers the panel holder from the detaching section to the holder stocker.

7. A test line as set forth in claim 6,
wherein the panel holders are each adapted to hold the display panel to be tested in a removable manner,
the holder base being adapted to hold the selected panel holder in a removable manner, and supply electric power and an image signal to the selected panel holder,
the panel holder comprising:
a mount base on which the display panel to be tested is removably mounted;
a drive circuit which receives the electric power and the image signal from the holder base and outputs a display panel lighting signal; and
a press-fit connection member which is removably attached to the mounted display panel to establish press-fit connection between an electrode terminal of the mounted display panel and a signal terminal of the drive circuit by a resilient force of a resilient member thereof.

8. A test line as set forth in claim 7, wherein the press-fit connection member includes a contact member which brings the electrode terminal of the mounted display panel and the signal terminal of the drive circuit into contact with each other, and the resilient member is a biasing member which applies a pressure to the contact member.

9. A test line as set forth in claim 6, wherein the plurality of panel holders include plural types of panel holders for different types of display panels, and one of the plural types of panel holders which conforms to the display panel to be tested is mounted on the holder base.

10. A test line as set forth in claim 6, wherein the panel holders each have a handle for transportation.

11. A test line as set forth in claim 7, wherein the resilient member is a compression spring.
